(19) United States
(12) Patent Application Publication
(10) Pub. No.: US 2026/0370126 A1
(43) Pub. Date: Nov. 19, 2026

(54) DRIVE DEVICE FOR REVERSE CONDUCTION SEMICONDUCTOR SWITCHING ELEMENT AND POWER CONVERSION DEVICE USING THE SAME

(71) Applicant: Mitsubishi Electric Corporation, Tokyo (JP)

(72) Inventor: Kohei ONDA, Tokyo (JP)

(73) Assignee: Mitsubishi Electric Corporation, Tokyo (JP)

(21) Appl. No.: 19/155,267

(22) PCT Filed: May 18, 2023
(86) PCT No.: PCT/JP2023/018574

§ 371 Date: Aug. 11, 2025

(51) Int. Cl. H02M 1/088; H02M 1/32; H02M 1/38; H02M 3/158; H02M 7/5387; H03K 17/567

(52) U.S. Cl. CPC H02M 1/088; H02M 1/32; H02M 1/38; H02M 3/158; H02M 7/53871; H03K 17/567

(57) ABSTRACT

A drive device for a reverse conduction semiconductor switching element in which a semiconductor switching element and a rectification element are integrated, includes: an ON-permission signal generation unit which receives an ON/OFF command signal for turning on or off the reverse conduction semiconductor switching element and generates an ON-permission signal; and a gate drive unit which receives the ON-permission signal and generates drive voltage to be applied to a gate terminal of a semiconductor switching element. If inter-main terminal voltage of the semiconductor switching element in a period in which the reverse conduction semiconductor switching element is turned off is greater than first reference voltage, the ON-permission signal is set into an ON state, and if the inter-main terminal voltage is smaller than second reference voltage which is different from first reference voltage, the ON-permission signal is changed into an OFF state.

### TECHNICAL FIELD

The present disclosure relates to a drive device for a reverse conduction semiconductor switching element, and a power conversion device using the same.

### BACKGROUND ART

A power conversion device including a power conversion unit and a control unit for controlling the power conversion unit, such as an inverter device, performs power conversion through operation of turning on/off semiconductor switching elements, and is widely applied to consumer usage, industrial usage, vehicular usage, railroad usage, and the like. Examples of the semiconductor switching elements include voltage-driven semiconductor switching elements such as IGBT (Insulated-Gate-Bipolar-Transistor) and MOSFET (Metal-Oxide-Semiconductor Field-Effect Transistor). In order to control such a semiconductor switching element, a drive device for the semiconductor switching element is needed. In general, such a drive device for the semiconductor switching element has a function of controlling the conduction state of the semiconductor switching element by applying voltage to the gate of the semiconductor switching element.

In recent years, a reverse conduction IGBT in which an IGBT and a diode connected in antiparallel to the IGBT are integrated has been increasingly applied, whereby the chip size is reduced, leading to cost reduction, and the thermal resistance is reduced, leading to size reduction of the power converter.

In a drive circuit for the semiconductor switching element in the power conversion device, control that does not depend on the direction of load current is applied for the purpose of simplifying control of the semiconductor switching element, and it is general that the gate of the IGBT is turned on even when the diode of the reverse conduction IGBT is in a conducting state. However, when the gate of the IGBT is turned on during the conducting state of the diode, a parasitic n-channel MOSFET operates, and as a result, bipolar operation of the diode is hindered, so that forward voltage increases. Therefore, as the reverse conduction IGBT, a separated reverse conduction IGBT provided with a separation region between an IGBT region and a diode region so as to inhibit mutual interference is generally adopted.

In this regard, for the purpose of improving the current density by elimination of the separation region, a drive method of inhibiting the gate of the IGBT from being turned on when the diode of the reverse conduction IGBT is in a conducting state is devised, and accordingly, application of a non-separated reverse conduction IGBT is attempted.

In such a non-separated reverse conduction IGBT, a sensing diode for monitoring current flowing through the diode when the diode of the reverse conduction IGBT is in a conducting state is added, and control is performed so that the gate of the IGBT is not turned on when the diode of the reverse conduction IGBT is in a conducting state, thereby suppressing increase in forward voltage of the diode due to operation of a parasitic n-channel MOSFET (see, for example, Patent Document 1).

In the method disclosed in Patent Document 1, since current flowing through the diode is directly detected, the gate is accurately prevented from being turned on when the diode is in a conducting state. However, since the sensing diode for monitoring is added, the chip area of the reverse conduction IGBT increases, leading to cost increase.

In a non-separated reverse conduction IGBT with which such a sensing diode for monitoring is not needed, the following method is known. In a period in which an upper arm and a lower arm of a leg circuit formed by connecting a plurality of reverse conduction IGBTs in series are both OFF, the gate is turned on, on the basis of main terminal voltage of the reverse conduction IGBT, and the ON state of the gate is retained until an OFF command for the reverse conduction IGBT is inputted from a higher-level control unit, thereby inhibiting increase in forward voltage of the diode due to operation of the parasitic n-channel MOSFET (see, for example, Patent Document 2).

Meanwhile, it is known that operation of the parasitic n-channel MOSFET when the diode is in a conducting state causes reduction in a short-circuit withstand capacity, as an IGBT-specific problem. In general, modes in which the upper arm and the lower arm of the leg circuit are short-circuited include short-circuit occurring when an IGBT is turned on (type-1 short-circuit), short-circuit occurring when an IGBT is in a conducting state (type-2 short-circuit), and short-circuit occurring in a period in which the gate of an IGBT is turned on when the diode is in a conducting state (type-3 short-circuit). Here, in an IGBT in a MOSFET mode in which efficiency of injection of holes from a collector p-channel layer is reduced and the ratio of electron current is increased, the space charge in a drift layer becomes negative during short-circuit, so that the electric field intensity on the back side increases, resulting in reduction of the short-circuit withstand capacity, as reported (see, for example, Non-Patent Document 1). A situation similar to this occurs in type-3 short-circuit of the reverse conduction IGBT.

That is, in the reverse conduction IGBT, operation of the parasitic n-channel MOSFET when the diode connected in antiparallel to the IGBT is in a conducting state causes reduction in the short-circuit withstand capacity during this period, as a new problem, and depending on element designing, it can be assumed that breakdown occurs due to time constants at which it is difficult to perform protection by known short-circuit protection technology. In particular, a collector voltage detection (Desat) configuration which is general as short-circuit protection technology can be easily applied at low cost, but has a great detection delay and therefore it is difficult to perform protection against type-3 short-circuit of the reverse conduction IGBT. For performing protection in this short-circuit mode, an expensive short-circuit detection method needs to be adopted.

### CITATION LIST

### Patent Document

Patent Document 1: Japanese Laid-Open Patent Publication No. 2008-72848
Patent Document 2: Japanese Laid-Open Patent Publication No. 2014-216932

### Non-Patent Document

Non-Patent Document 1: Simulation studies for short-circuit current crowding of MOSFET-Mode IGBT, ISPSD, 2014

### SUMMARY OF THE INVENTION

### Problem to be Solved by the Invention

In the method disclosed in Patent Document 1, a sensing diode for monitoring is added, so that the chip area of the reverse conduction IGBT increases, leading to cost increase.

In the method disclosed in Patent Document 2, a sensing diode for monitoring is not needed, but collector voltage is determined only in a period in which the upper arm and the lower arm forming the leg circuit are both OFF. Therefore, at the timing of commutating from conduction of the diode to conduction of the IGBT, the gate cannot be appropriately turned on.

Further, the gate-ON state is retained until an OFF command for the reverse conduction IGBT is issued from the higher-level control unit. Therefore, when current during the gate-ON state is commutated from the direction of flowing to the IGBT to the direction of flowing to the diode, increase in forward voltage of the diode inevitably occurs due to operation of the parasitic n-channel MOSFET.

At this time, the forward voltage can reach tens to hundreds of volts, which causes not only mere loss increase but also a problem involving reliability.

Further, due to operation of the parasitic n-channel MOSFET when the diode is in a conducting state, the short-circuit withstand capacity is reduced, which might cause reduction in the withstand capacity against type-3 short-circuit of the reverse conduction IGBT.

The present disclosure has been made to solve the above problem, and an object of the present disclosure is to provide such a configuration that a gate is inhibited from being turned on when a diode of a reverse conduction IGBT is in a conducting state, and even when current is commutated to the diode during a gate-ON period, increase in forward voltage of the diode is prevented and breakdown due to type-3 short-circuit occurring in a gate-ON period when the diode is in a conducting state is prevented.

### Means to Solve the Problem

A drive device for a reverse conduction semiconductor switching element according to the present disclosure is a drive device for a reverse conduction semiconductor switching element in which a semiconductor switching element and a rectification element connected in antiparallel to the semiconductor switching element are integrated, the drive device including: an ON-permission signal generation unit which receives an ON/OFF command signal for turning on or off the reverse conduction semiconductor switching element and generates an ON-permission signal; a gate drive unit which receives the ON-permission signal and generates drive voltage to be applied to a gate terminal of the semiconductor switching element; and a voltage determination unit which performs comparison and determination of inter-main terminal voltage between first and second main terminals of the semiconductor switching element, with first reference voltage and second reference voltage which is different from the first reference voltage. Through logical combination of a determination signal from the voltage determination unit and the ON/OFF command signal, if the inter-main terminal voltage in a period in which the reverse conduction semiconductor switching element is turned off is greater than the first reference voltage, the ON-permission signal is set into an ON state, and if the inter-main terminal voltage in a period in which the reverse conduction semiconductor switching element is turned off is smaller than the second reference voltage, the ON-permission signal is changed into an OFF state.

A power conversion device according to the present disclosure is configured such that, for each reverse conduction semiconductor switching elements of an upper arm and a lower arm connected in series, the drive devices for the reverse conduction semiconductor switching elements according to the present disclosure are provided, respectively.

### Effect of the Invention

With the drive device for the reverse conduction semiconductor switching element according to the present disclosure, a gate is inhibited from being turned on when a diode of a reverse conduction semiconductor switching element is in a conducting state, and even when current is commutated to the diode during a gate-ON period, increase in forward voltage of the diode can be prevented and breakdown due to type-3 short-circuit occurring in a gate-ON period when the diode is in a conducting state can be prevented.

### BRIEF DESCRIPTION OF THE DRAWINGS

FIG. 1 is a block diagram showing a configuration example of a drive device for a reverse conduction semiconductor switching element according to embodiment 1.

FIG. 2 is a block diagram showing a Specific example of the drive device for the reverse conduction semiconductor switching element according to embodiment 1.

FIG. 3 shows an example of a time chart of signals in a normal state in the specific example of the drive device for the reverse conduction semiconductor switching element according to embodiment 1.

FIG. 4 shows an example of a time chart of a second voltage determination signal in the specific example of the drive device for the reverse conduction semiconductor switching element according to embodiment 1.

FIG. 5 shows an example of a time chart of signals in a case of short-circuit in the specific example of the drive device for the reverse conduction semiconductor switching element according to embodiment 1.

FIG. 6 is a block diagram showing a configuration example of a drive device for a reverse conduction semiconductor switching element according to embodiment 2.

FIG. 7 is a block diagram showing a specific example of the drive device for the reverse conduction semiconductor switching element according to embodiment 2.

FIG. 8 shows an example of a time chart of signals in a normal state in the specific example of the drive device for the reverse conduction semiconductor switching element according to embodiment 2.

FIG. 9 is a block diagram showing a configuration example of a drive device for a reverse conduction semiconductor switching element according to embodiment 3.

FIG. 10 is a block diagram showing a specific example of the drive device for the reverse conduction semiconductor switching element according to embodiment 3.

FIG. 11 shows an example of time charts of signals in a normal state in the specific example of the drive device for the reverse conduction semiconductor switching element according to embodiment 3.

FIG. 12 is a block diagram showing a configuration example of a drive device for a reverse conduction semiconductor switching element according to embodiment 4.

FIG. 13 is a block diagram showing a specific example of the drive device for the reverse conduction semiconductor switching element according to embodiment 4.

FIG. 14 shows an example of time charts of signals in a normal state in the specific example of the drive device for the reverse conduction semiconductor switching element according to embodiment 4.

FIG. 15 shows a configuration example of a power conversion device using a drive device for a reverse conduction semiconductor switching element according to embodiment 5.

FIG. 16 shows a configuration example of a power conversion device using a drive device for a reverse conduction semiconductor switching element according to embodiment 6.

FIG. 17 shows a configuration example of a power conversion device using a drive device for a reverse conduction semiconductor switching element according to embodiment 7.

### DESCRIPTION OF EMBODIMENTS

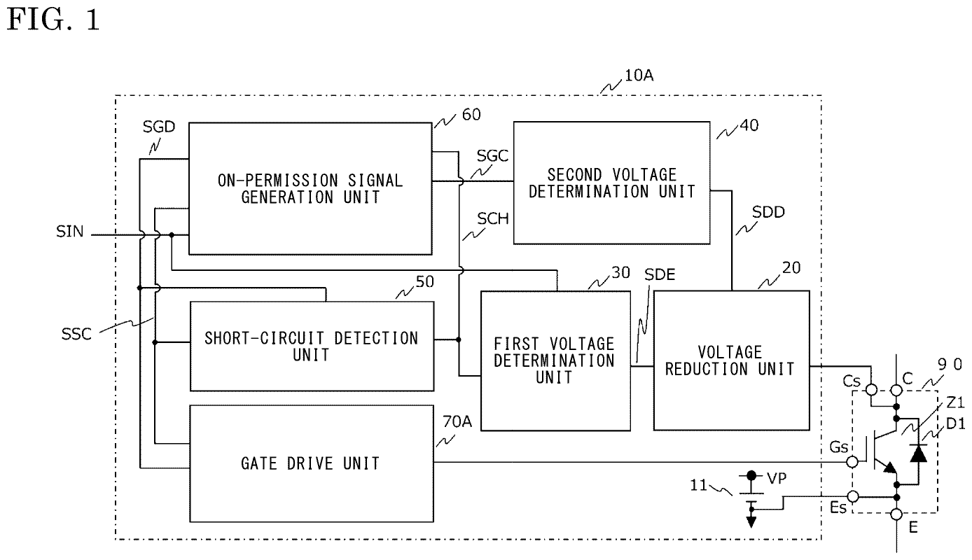

Hereinafter, embodiments will be described with reference to the drawings. In the drawings, the same reference characters denote the same or corresponding parts. FIG. 1 to FIG. 17 relate to exemplary embodiments and the present disclosure is not limited by the drawings.

### Embodiment 1

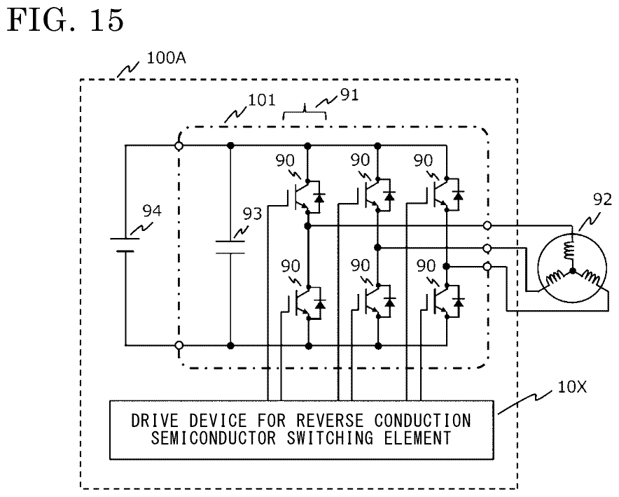

FIG. 1 is a block diagram showing a configuration of a drive device 10A for a reverse conduction semiconductor switching element according to embodiment 1. The following example is assumed to be applied to a configuration of a leg circuit 91 in which a plurality of reverse conduction semiconductor switching elements 90 are connected in series as shown in FIG. 15 to FIG. 17.

As an example of the reverse conduction semiconductor switching element 90, a reverse conduction IGBT in which an IGBT_Z1 and a diode D1 are integrated is shown. The reverse conduction semiconductor switching element 90 has a collector sensing terminal Cs which is a first main terminal and an emitter control terminal Es which is a second main terminal, and a conducting/non-conducting state between a collector C and an emitter E is controlled in accordance with gate voltage Vge applied between a gate terminal Gs and the emitter control terminal Es.

In the shown example, the drive device 10A for the reverse conduction semiconductor switching element includes a voltage reduction unit 20, a first voltage determination unit 30, a second voltage determination unit 40, a short-circuit detection unit 50, an ON-permission signal generation unit 60, and a gate drive unit 70A, and positive power supply voltage VP generated with the emitter control terminal Es as a reference is applied as a gate drive power supply to the gate terminal Gs. In the present embodiment, in a period in which the gate is turned off, voltage applied to the gate terminal Gs is zero, but the gate drive power supply may be configured so as to apply negative power supply voltage VN. Besides the gate drive power supply, a control power supply for operating a logic circuit or the like may be provided separately. In the present embodiment, a control power supply of 5V is provided, but this is not shown, for the purpose of simplification.

The drive device 10A for the reverse conduction semiconductor switching element receives an ON/OFF command signal SIN for turning on or off the reverse conduction semiconductor switching element 90, which is transmitted from a higher-level logic unit such as a microcomputer, and on the basis of voltage of the collector sensing terminal Cs of the reverse conduction semiconductor switching element 90, generates an appropriate ON-permission signal SGD for the reverse conduction semiconductor switching element 90, and detects short-circuit of the reverse conduction semiconductor switching element 90, thus functioning to appropriately perform protection. The voltage of the collector sensing terminal Cs, i.e., inter-main terminal voltage Vce between the first main terminal and the second main terminal, is reduced to a signal level by the voltage reduction unit 20, and resultant signals SDE and SDD are inputted to the first voltage determination unit 30 and the second voltage determination unit 40, respectively.

The first voltage determination unit 30 transmits, to the ON-permission signal generation unit 60, a first voltage determination signal SCH resulting from determination that the input signal SDE in a period in which the ON/OFF command signal SIN indicates OFF is not smaller than a first reference value. The second voltage determination unit 40 transmits, to the ON-permission signal generation unit 60, a second voltage determination signal SGC resulting from determination that voltage of the input signal SDD is not greater than a second reference value. In response to generation of the first voltage determination signal SCH, the ON-permission signal generation unit 60 changes the ON-permission signal SGD into an ON state and retains this state by an internal retention circuit, and in response to generation of the second voltage determination signal SGC or change of indication of the ON/OFF command signal from ON to OFF, the ON-permission signal generation unit 60 changes the ON-permission signal SGD into an OFF state.

In a period in which the ON-permission signal SGD indicates an ON state, if the first voltage determination signal SCH has been generated for a predetermined time or longer, the short-circuit detection unit 50 determines that the reverse conduction semiconductor switching element 90 is short-circuited, and transmits a short-circuit detection signal SSC retained for a predetermined period, to the gate drive unit 70A and the ON-permission signal generation unit 60. The generated ON-permission signal SGD is logically combined with the short-circuit detection signal SSC by the gate drive unit 70A, and if short-circuit is not detected, current of the ON-permission signal SGD is amplified to drive the gate terminal Gs. If the short-circuit detection unit 50 detects short-circuit, the ON-permission signal SGD and the short-circuit detection signal SSC are logically combined in the gate drive unit 70A, and the gate terminal Gs is controlled so as to turn off the gate. At the same time, the short-circuit detection signal SSC is transmitted to the ON-permission signal generation unit 60, and the ON-permission signal SGD is changed into an OFF state.

The gate drive unit 70A has a soft interruption function so that, when the short-circuit detection signal ssc is generated, the gate drive unit 70A changes a gate drive force so as to reduce arising surge voltage by interrupting the short-circuit current as necessary. However, a configuration for implementing this is not shown, for the purpose of simplification. The blocks that transmit/receive signals and the block that logically combines signals are not limited to the configuration shown in FIG. 1. The combination of blocks and transmission/reception of signals may be changed in various manners.

The ON/OFF command signal SIN is transmitted between a reference potential of a higher-level logic unit such as a microcomputer and the emitter reference potential Es, and therefore is transmitted/received by isolated communication via an optical conversion module, a photocoupler, a pulse transformer, or another level shift IC. However, this is not shown, for the purpose of simplification. Also, the gate drive power supply 11 is isolated as an isolated power supply, but the details of a generation circuit therefor and the like are not shown, for the purpose of simplification.

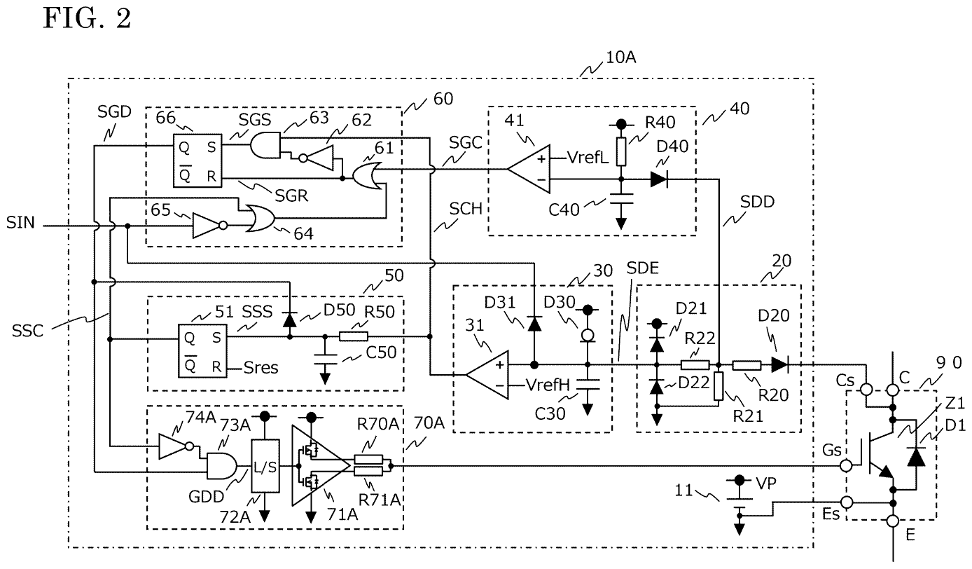

FIG. 2 shows a specific example of the drive device 10A for the reverse conduction semiconductor switching element 90 according to embodiment 1. The voltage reduction unit 20 has a configuration of reducing the potential of the collector sensing terminal Cs through rectification operation of a high-voltage diode D20 and voltage division by resistors R20 to R22, as an example. However, various known configurations such as a configuration of dividing voltage by only a resistor and a configuration using a constant voltage diode or the like may be adopted.

The first voltage determination unit 30 has a filter characteristic based on a charging time constant of a filter capacitor C30 and a constant current diode D30, and a discharging time constant defined by the filter capacitor C30 and the resistors R20 and R22, and if the first voltage determination unit 30 determines that the input signal SDE is greater (higher) than first reference voltage VrefH by a comparator 31, the first voltage determination unit 30 generates a first voltage determination signal SCH. The second voltage determination unit 40 has a filter characteristic based on a discharging time constant defined by a filter capacitor C40 and the resistor R20, and a charging time constant defined by a filter capacitor C40 and a resistor R40, and if the second voltage determination unit 40 determines that the input voltage SDD is smaller (lower) than second reference voltage VrefL by a comparator 41, the second voltage determination unit 40 generates a second voltage determination signal SGC.

In the ON-permission signal generation unit 60, by an internal logic circuit, if the ON/OFF command signal SIN indicates ON and the short-circuit detection signal SSC is at a Lo level, the first voltage determination signal SCH is inputted to a set input part of a flip-flop circuit 66, thus being logically combined so that the ON-permission signal SGD is retained at a Hi level. When the second voltage determination signal SGC is generated, or at the timing when the ON/OFF command signal SIN indicates OFF, or when the short-circuit detection signal SSC is generated, a reset input is performed to the flip-flop circuit 66, thus being logically combined so that the ON-permission signal SGD is retained in an OFF state.

In the short-circuit detection unit 50, by an internal logic circuit, the first voltage determination signal SCH is subjected to filter masking with a time constant of a resistor R50 and a filter capacitor C50, and if this is exceeded, a set input is performed to the flip-flop circuit 51 so that the short-circuit detection state is retained. Regarding reset of the flip-flop circuit 51, a configuration of performing reset by an instruction from a microcomputer or the like, or a configuration of performing reset by a predetermined time constant, may be adopted, or the flip-flop circuit 51 itself may be a time-limit type such as a monostable multivibrator. In a delay period until the ON/OFF command signal SIN indicates shift from OFF to ON and the ON-permission signal SGD indicates shift from OFF to ON by determination in the first voltage determination unit 30, if the first voltage determination signal SCH is retained in a Hi-level state for the time constant of the filter or longer, a normal state is erroneously detected as short-circuit. Therefore, for preventing this, a short-circuit detection input signal SSS is logically combined with the ON-permission signal SGD by a diode D50.

The gate drive unit 70A logically combines the ON-permission signal SGD and the short-circuit detection signal SSC by an internal logic circuit, to generate a buffer input signal GDD, the level thereof is shifted from a logic level to a level of the gate drive power supply VP by a level shift circuit 72A, and the current thereof is amplified by a buffer circuit 71A, to charge/discharge the gate. The charging/discharging time constant is adjusted by an ON gate resistor R70A and an OFF gate resistor R71A. The configuration of the buffer circuit 71A and the adjustment method for gate charging/discharging are not limited to the above, and various configurations such as a buffer formed by a bipolar transistor, and a constant current drive circuit, may be adopted.

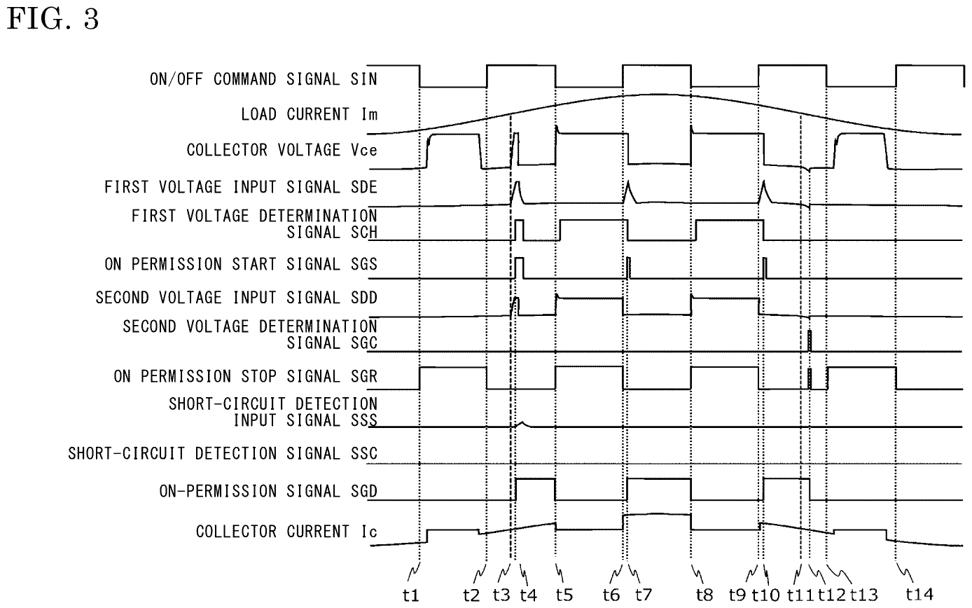

FIG. 3 shows an example of a time chart of signals in a normal state in a specific example 1 of the drive device 10A for the reverse conduction semiconductor switching element 90 according to embodiment 1. A period in which load current Im is negative corresponds to a state in which current flows through the diode D1 of the reverse conduction semiconductor switching element 90. According to the present disclosure, the ON-permission signal SGD can indicate OFF even if the ON/OFF command signal SIN is at a Hi level in the above period. Time t3 is a timing of commutating from conduction of the diode D1 to conduction of the IGBT_Z1. Since a configuration in which the ON-permission signal SGD is changed into an ON state on the basis of the first voltage determination signal SCH in a period in which the IGBT_Z1 is OFF is adopted, it is possible to appropriately perform control at a timing when change from OFF to ON is needed. On the other hand, time t11 is a timing of shifting from a state in which current flows through the IGBT_Z1 of the reverse conduction semiconductor switching element 90 to a state in which current flows through the diode D1, and since the ON-permission signal SGD has been in an ON state, forward voltage of the diode increases, so that the collector voltage Vce becomes a great negative value. This is detected by the second voltage determination unit 40, and at time t12, the ON-permission signal SGD is changed into an OFF state.

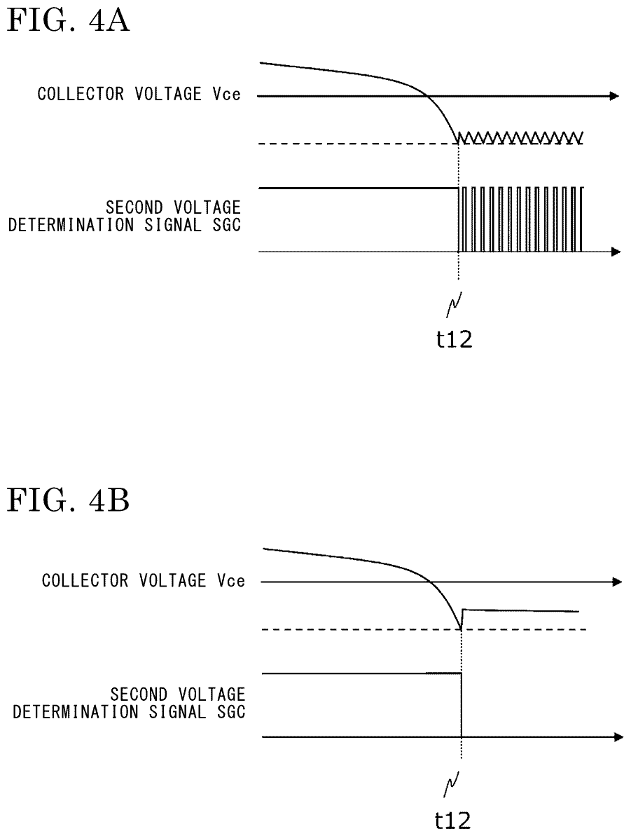

It is desirable that the first reference voltage VrefH which is a reference value for the first voltage determination unit 30 is greater than the second reference voltage VrefL which is a reference value for the second voltage determination unit 40. FIG. 4 illustrates the reason, and shows the collector voltage Vce and the second voltage determination signal SGC around time t12 at which current is commutated from the IGBT_Z1 to the diode D1. FIG. 4A shows a waveform in a case where the first reference voltage VrefH and the second reference voltage VrefL are equal to each other. A case where the first reference voltage VrefH is smaller than the second reference voltage VrefL exhibits the same result as in the above case, and therefore is not shown. Here, at time t12, it is detected that the forward voltage has increased due to operation of the parasitic n-channel MOSFET, and the ON-permission signal SGD comes into an OFF state. As a result, the forward voltage decreases, so that the ON-permission signal SGD is comes into an ON state again by determination in the first voltage determination unit 30. Thus, the forward voltage increases again.

An ON permission start signal SGS, the second voltage input signal SDD, an ON permission stop signal SGR, and the short-circuit detection input signal SSS are as shown in the drawing.

As described above, if the inter-main terminal voltage Vce of the reverse conduction semiconductor switching element 90 is compared and determined using only a single reference voltage, there is a disadvantage of potentially leading to an oscillation mode, in the method disclosed in Patent Document 2, for example. On the other hand, in FIG. 4B, the first reference voltage VrefH is set to be greater than the second reference voltage VrefL, and the difference therebetween is set to be greater than the difference between forward voltages arising in ON and OFF states of the gate, whereby it is possible to prevent oscillation of the ON-permission signal SGD.

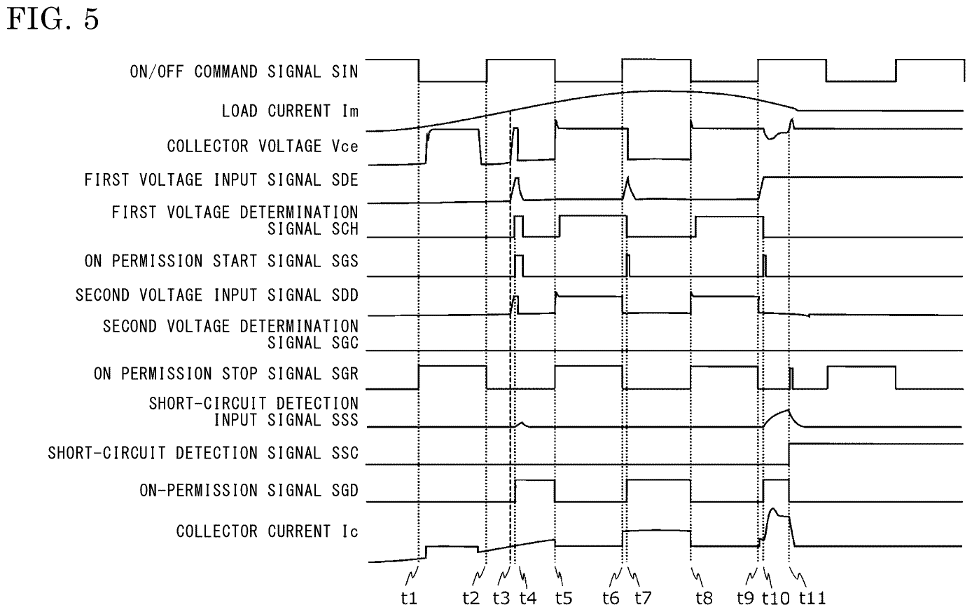

FIG. 5 shows an example of a time chart of signals in a case of short-circuit in the specific example 1 of the drive device 10A for the reverse conduction semiconductor switching element 90 according to embodiment 1. When the upper arm and the lower arm forming the leg circuit are short-circuited at time t9, the collector voltage Vce, i.e., the first voltage input signal SDE, is retained at a high level, so that the first voltage determination signal SCH becomes a Hi level for a predetermined time. Thus, the short-circuit detection signal SSC is generated and the ON-permission signal SGD is changed into an OFF state.

The ON permission start signal SGS, the second voltage input signal SDD, the ON permission stop signal SGR, and the short-circuit detection input signal SSS are as shown in the drawing.

As described above, in the drive device 10A for the reverse conduction semiconductor switching element 90 according to embodiment 1, the gate is inhibited from being turned on when the diode D1 of the reverse conduction semiconductor switching element 90 is in a conducting state, and even when current during the gate-ON period is commutated to the diode D1, increase in forward voltage of the diode D1 can be prevented and breakdown due to type-3 short-circuit occurring in the gate-ON period when the diode D1 is in a conducting state can be prevented.

In particular, the first voltage determination unit 30 is formed by a general collector voltage detection (Desat) configuration, and using this, a function of changing the ON-permission signal into an ON state and a function of detecting short-circuit are both implemented, whereby further cost reduction can be achieved. Further, a gate-ON period during the conducting state of the diode D1 can be reduced to an extremely short time, e.g., hundreds of nanoseconds, whereby breakdown due to type-3 short-circuit, which is a problem of the reverse conduction IGBT, can be assuredly prevented. Therefore, it is possible to adopt a collector voltage detection configuration having high versatility at low cost, without providing an expensive short-circuit detection circuit.

### Embodiment 2

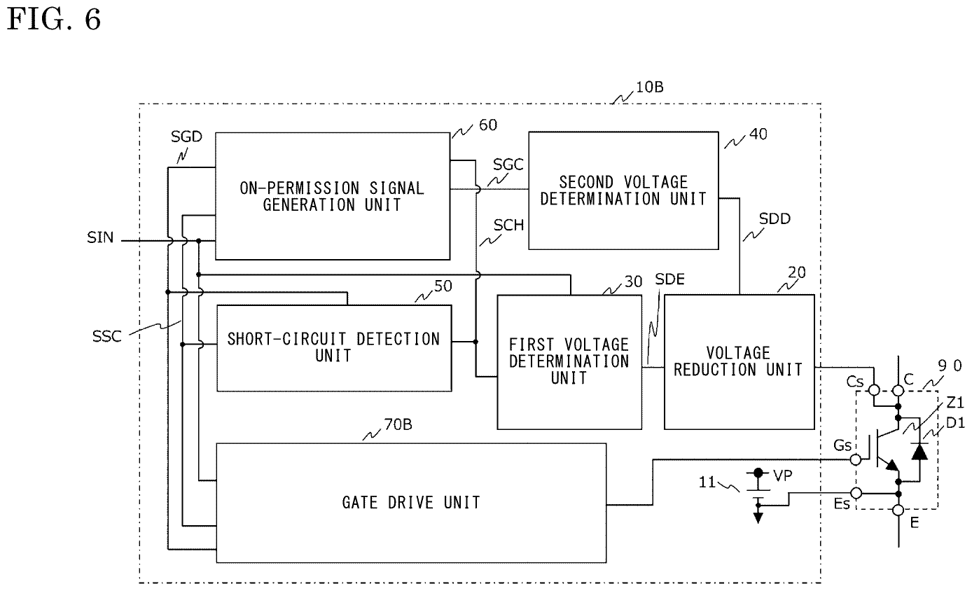

FIG. 6 is a block diagram showing a configuration of a drive device 10B for a reverse conduction semiconductor switching element 90 according to embodiment 2. Embodiment 2 is different from embodiment 1 in that the ON/OFF command signal SIN is inputted to a gate drive unit 70B. The gate drive unit 70B drives the gate terminal Gs on the basis of the ON/OFF command signal SIN in addition to the ON-permission signal SGD, and thus, through an operation mode of the reverse conduction semiconductor switching element 90 obtained from comparison between the above signals, the drive function for the gate terminal Gs can be implemented so as to reduce switching loss.

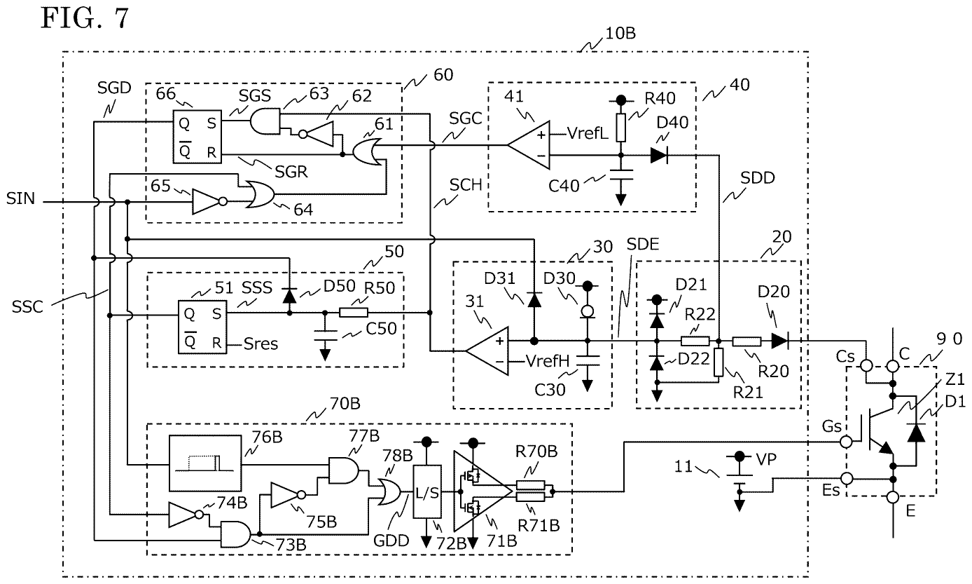

For example, FIG. 7 is a block diagram showing a specific example 1 of the drive device 10B for the reverse conduction semiconductor switching element. In a state in which the ON-permission signal SGD indicates an OFF state and the short-circuit detection signal SSC does not indicate detection of short-circuit, when the ON-permission signal SGD shifts from an ON state to an OFF state, i.e., at the timing when the conducting state of the diode D1 ends, a falling edge pulse generation circuit 76B receiving the ON/OFF command signal SIN generates an ON pulse having a predetermined width, to turn on the gate for a predetermined period.

Thus, the parasitic n-channel MOSFET of the reverse conduction semiconductor switching element 90 operates and carriers accumulated inside are decreased, whereby recovery current in subsequent recovery operation is reduced and therefore recovery loss can be reduced. The width of the ON pulse is equal to or longer than a time that is needed for decreasing the accumulated carriers and is short so that the influence of increase in forward voltage on loss is negligible.

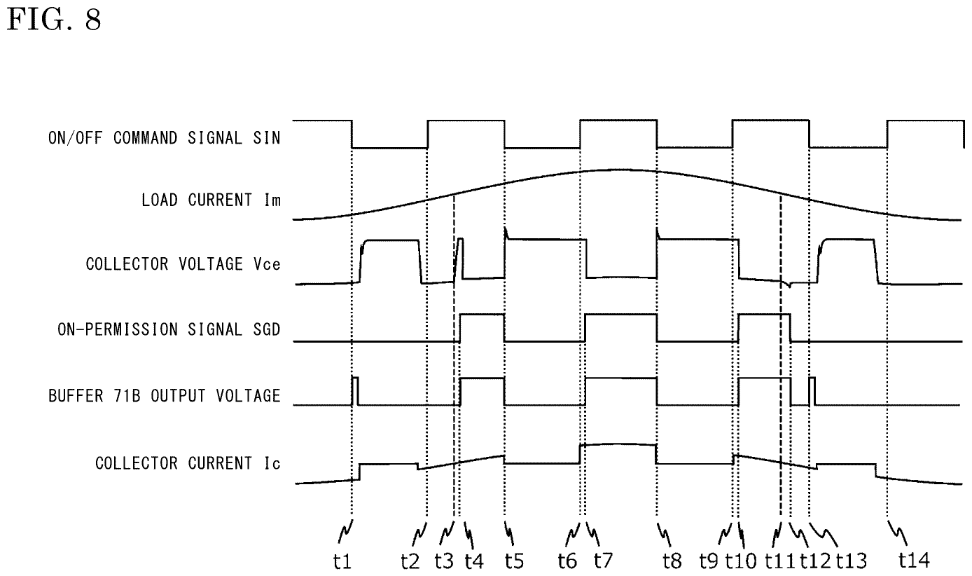

In order to prevent arm short-circuit in type-3 short-circuit, a dead time provided between the upper arm and the lower arm of the leg circuit needs to be longer than the ON pulse width. FIG. 8 shows an example of a time chart of signals. At time t13 when the ON/OFF command signal SIN indicates OFF during the conducting state of the diode D1, an ON pulse having a predetermined width is outputted as an output signal of the buffer 1B.

### Embodiment 3

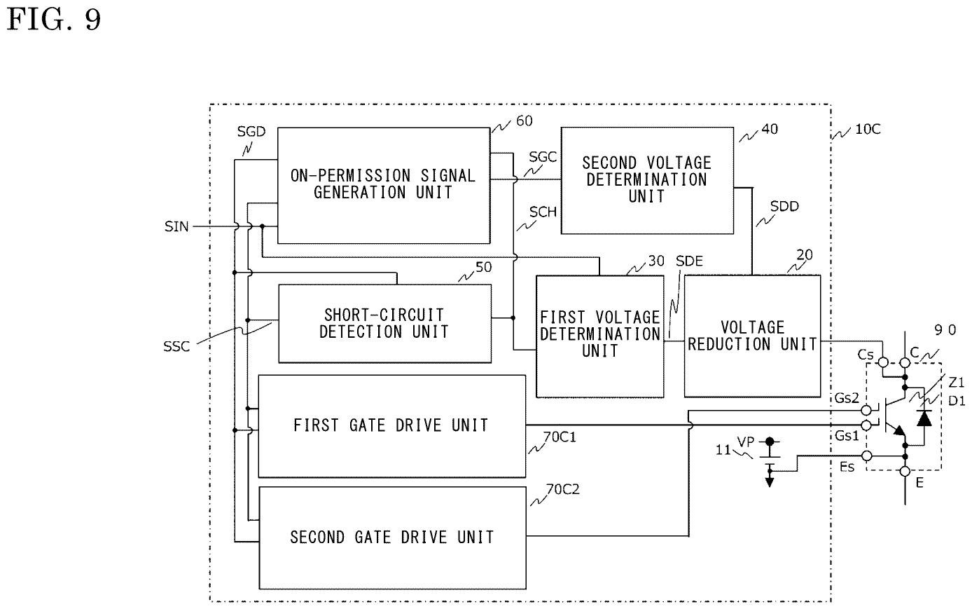

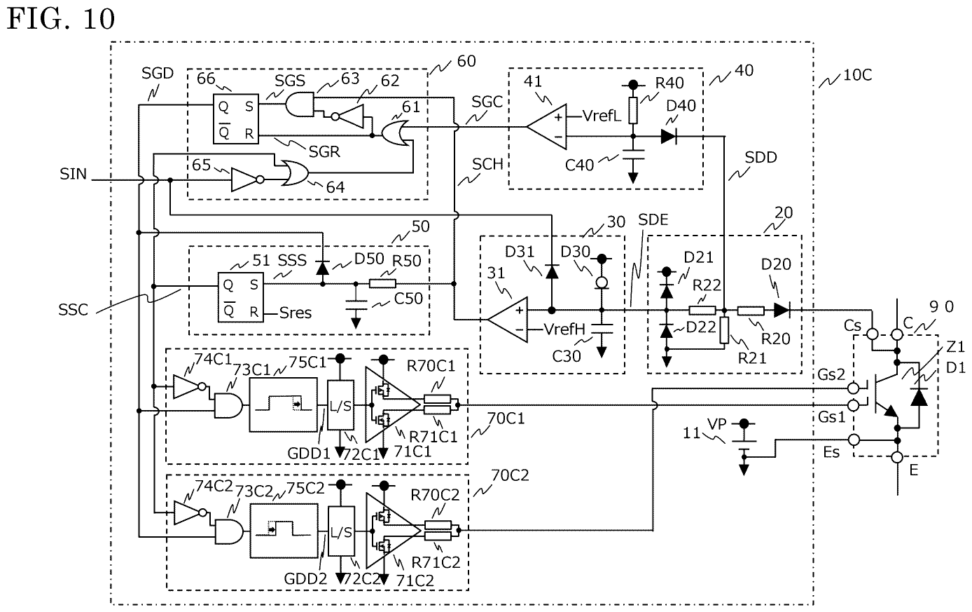

FIG. 9 is a block diagram showing a configuration example of a drive device 10C for a reverse conduction semiconductor switching element 90 according to embodiment 3. As compared to embodiment 1, in embodiment 3, the IGBT_Z1 to be driven is a double-gate semiconductor switching element including two gate terminals Gs1 and Gs2, and two gate drive units 7001 and 70C2 are provided correspondingly. FIG. 10 is a block diagram showing a specific example of the drive device 10C for the reverse conduction semiconductor switching element. The first gate drive unit 70C1 for driving the first gate terminal Gs1 has a falling delay circuit 75C1 on the input side and thus is configured to delay a falling timing of the ON-permission signal SGD. The second gate drive unit 70C2 for driving the second gate terminal Gs2 has a rising delay circuit 75C2 on the input side and is configured to delay a rising timing of the ON-permission signal SGD.

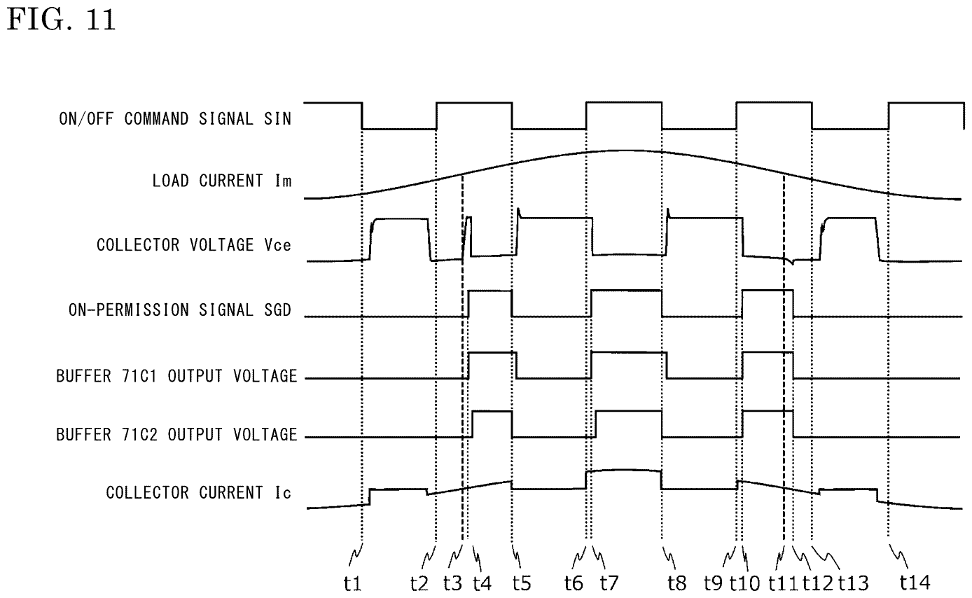

Thus, in a time chart of signals shown in FIG. 11, at time t5 and time t8, an OFF timing of output voltage of a buffer 71C1 is delayed relative to an OFF timing of output voltage of a buffer 71C2, and at time t4 and time t7, an ON timing of output voltage of the buffer 7102 is delayed relative to an ON timing of output voltage of the buffer 71C1. In the double-gate semiconductor switching element, time difference is provided between the two gate voltages as described above, whereby turn-off loss and turn-on loss can be reduced, and embodiment 3 is a configuration for implementing this.

### Embodiment 4

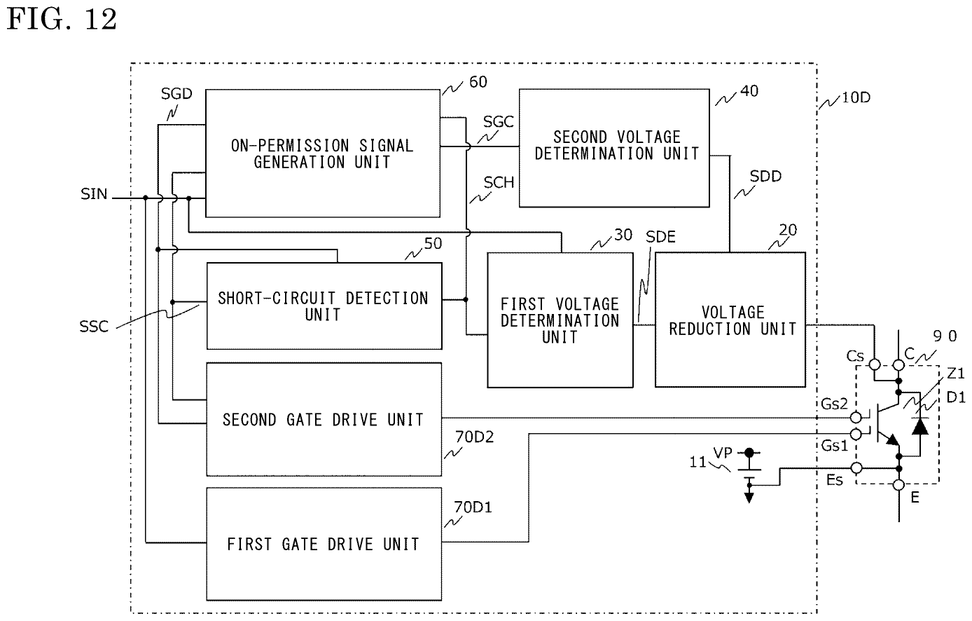

FIG. 12 is a block diagram showing a configuration example of a drive device 10D for a reverse conduction semiconductor switching element 90 according to embodiment 4. Embodiment 3 has used a parallel-type configuration in which, by respective gate voltages of the double-gate semiconductor switching element, cells connected to the respective gate terminals form channels independently, whereas embodiment 4 is different in using a series-type split-gate configuration in which channels are formed in a state in which two divided gates are both turned on. As compared to the drive device 10C for the reverse conduction semiconductor switching element according to embodiment 3, the drive device 10D for the reverse conduction semiconductor switching element according to embodiment 4 has a configuration in which an input signal to the first gate drive unit 70D1 which is one of the gate drive units is the ON/OFF command signal SIN from a higher-level logic unit, instead of the ON-permission signal SGD. A configuration of the second gate drive unit 70D2 is equivalent to that of the gate drive unit 70A according to embodiment 1.

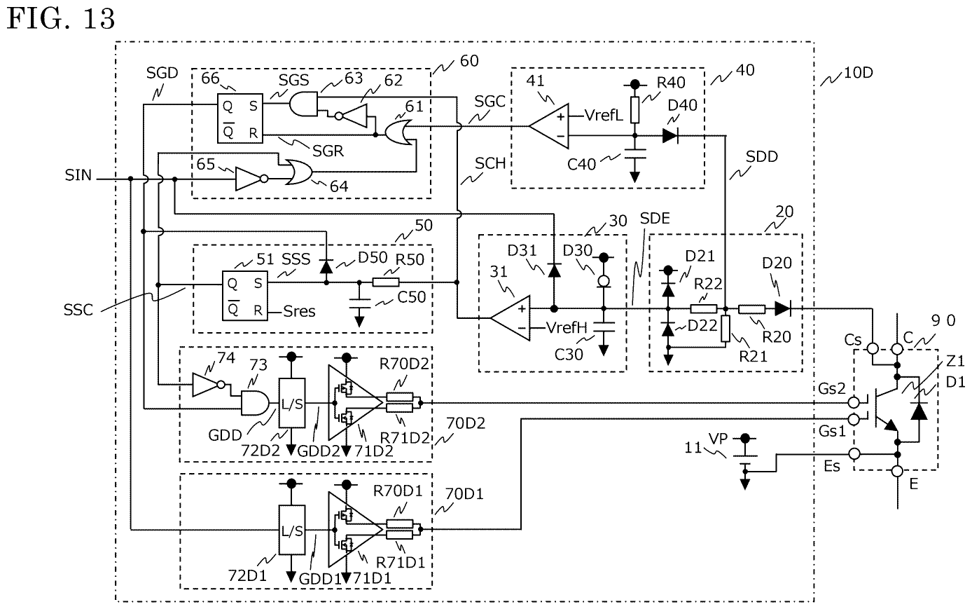

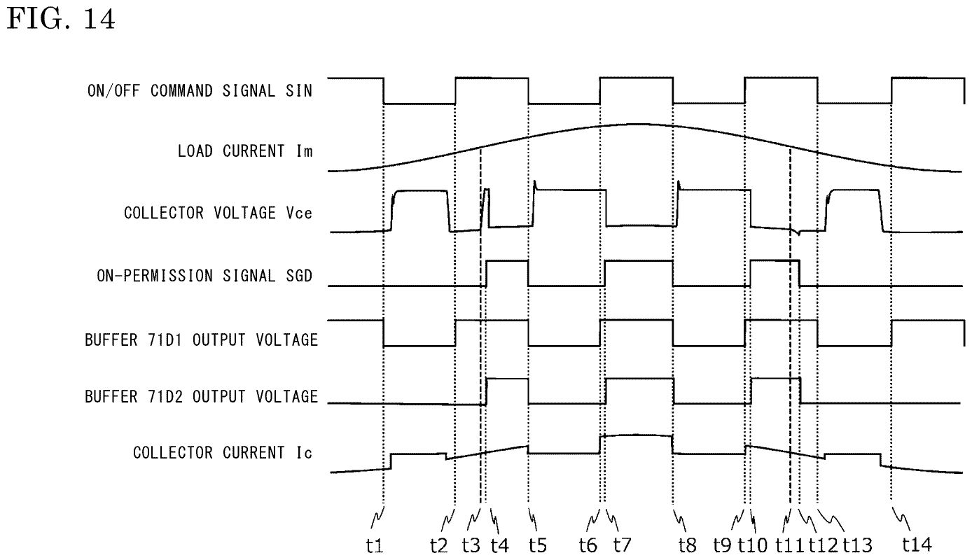

FIG. 13 is a block diagram showing a specific example 1 of the drive device 10D for the reverse conduction semiconductor switching element 90 according to embodiment 4, and difference from embodiment 3 is that the ON/OFF command signal SIN is directly inputted to a level shift circuit 72D1 of the first gate drive unit 7001. Thus, in a time chart of signals shown in FIG. 14, the ON/OFF command signal SIN is reproduced as it is, for the buffer 71D1. However, output voltage of the buffer 71D1 is appropriately generated by a method based on comparison and determination of the inter-main terminal voltage Vce with two reference voltages VrefH and VrefL as in the present disclosure. Therefore, the effects of preventing increase in forward voltage, and preventing breakdown due to type-3 short-circuit can be achieved even by the series-type split-gate semiconductor switching element as described above.

In embodiments 1 to 4, the drive device for the reverse conduction semiconductor switching element according to the present disclosure has been described. Hereinafter, power conversion devices, such as an inverter, a boost converter, and a boost inverter obtained by combining these, configured using the drive device for the reverse conduction semiconductor switching element, will be described with reference to FIG. 15 to FIG. 17.

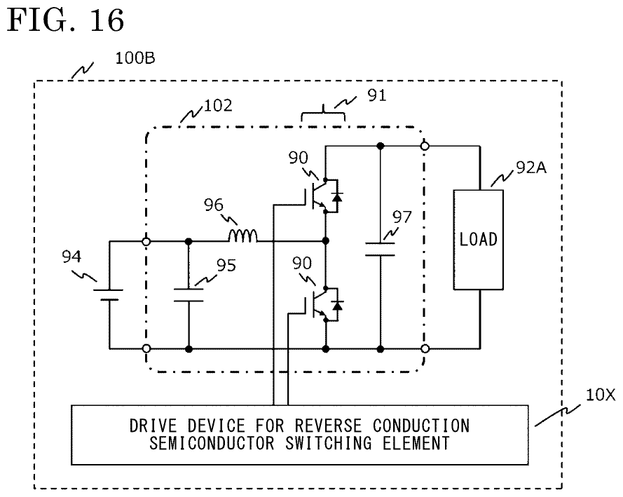

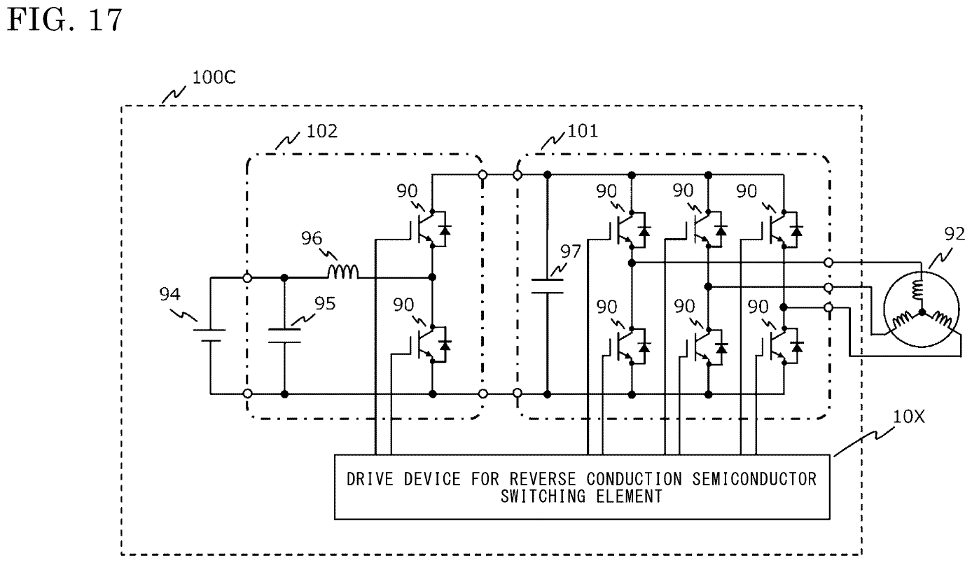

Power conversion devices such as an inverter shown in FIG. 15, a boost converter shown in FIG. 16, and a boost inverter shown in FIG. 17, which is obtained by combining these, are configured using one or a plurality of leg circuits 91 each composed of an upper arm and a lower arm in which a plurality of reverse conduction semiconductor switching elements 90 are connected in series. The reverse conduction semiconductor switching element 90 is configured as an IGBT module in which an IGBT and a diode are connected in antiparallel, as an example, and current flows alternately through the IGBT or the diode of the upper arm and the diode or the IGBT of the lower arm, in accordance with the direction of load current.

### Embodiment 5

FIG. 15 shows a configuration of a power conversion device as an inverter according to embodiment 5. A power conversion device 100A includes a power converter 101 having a plurality of reverse conduction semiconductor switching elements 90, and a drive device 10X for reverse conduction semiconductor switching elements, which drives each of the reverse conduction semiconductor switching elements 90 in the power converter 101, respectively. In this case, the power conversion device 100A is an inverter that converts DC power from a DC power supply 94 to AC power and supplies the AC power to an AC motor 92.

For each of the reverse conduction semiconductor switching elements 90, the drive device 10A for the reverse conduction semiconductor switching element according to embodiment 1 is provided, and a set of the drive devices 10A for the reverse conduction semiconductor switching elements is defined as the drive device 10X in the present embodiment.

The power converter 101 has a three-phase (U, V, W) configuration, and is an inverter circuit including a smoothing capacitor 93 between DC buses, and the leg circuits 91 for the respective phases. The leg circuit 91 for each phase is formed such that the upper arm and the lower arm each having the reverse conduction semiconductor switching element 90 are connected in series.

In the present embodiment, the reverse conduction semiconductor switching elements 90 in the power converter 101 are driven by the drive device 10X including a plurality of the drive devices 10A for the reverse conduction semiconductor switching elements according to embodiment 1. Thus, with a low-cost configuration, increase in forward voltage due to turning on of the gate when the diode is in a conducting state can be prevented and breakdown due to type-3 short-circuit can be prevented, whereby the power conversion device 100A with low loss and high reliability is obtained.

In the above example, the power converter 101 outputs AC voltage at two levels which are positive and negative. However, the power converter 101 may be an inverter that has any number of reverse conduction semiconductor switching elements 90 connected in series and parallel and is capable of multilevel voltage output. Also in this case, the power converter 101 has a configuration including the leg circuit 91 in which the upper arm and the lower arm each having the reverse conduction semiconductor switching element 90 are connected in series.

### Embodiment 6

FIG. 16 shows a configuration of a power conversion device as a boost converter according to embodiment 6. A power conversion device 100B includes a power converter 102 having a plurality of reverse conduction semiconductor switching elements 90, and the drive device 10X for reverse conduction semiconductor switching elements, which drives each of the reverse conduction semiconductor switching element 90 in the power converter 102, respectively. In this case, the power conversion device 100B operates as a boost converter which boosts DC voltage of the DC power supply 94 and supplies the boosted DC voltage to the DC load 92A. As described above, the drive device 10X for the reverse conduction semiconductor switching elements is a set of the drive devices 10A for the reverse conduction semiconductor switching elements, which respectively drive the reverse conduction semiconductor switching elements 90.

The power converter 102 includes a smoothing capacitor 95 on the input side, a smoothing capacitor 97 on the output side, the leg circuit 91, and a boost reactor 96. The leg circuit 91 is formed such that the upper arm and the lower arm each having the reverse conduction semiconductor switching element 90 are connected in series.

Also in this case, with a low-cost configuration, increase in forward voltage due to turning on of the gate when the diode is in a conducting state can be prevented and breakdown due to type-3 short-circuit can be prevented, whereby the power conversion device 100B with low loss and high reliability is obtained.

Although the boost converter has been shown in FIG. 16, a buck converter, or a buck-boost converter formed by combining a boost converter and a buck converter, is also applicable.

### Embodiment 7

FIG. 17 shows a configuration of a power conversion device as a boost inverter formed by combining an inverter and a boost converter, according to embodiment 7. A power conversion device 100C includes a main circuit (power converter) in which the power converter 102 shown in FIG. 16 is connected to the DC side of the power converter 101 shown in FIG. 15, and the drive device 10X which drives the reverse conduction semiconductor switching elements 90. In this case, in the power conversion device 100C, DC voltage of the DC power supply 94 is stepped up by the power converter 102, the stepped-up DC power is converted to AC power by the power converter 101, and the AC power is supplied to the AC motor 92. The power conversion device 1000 operates as a boost inverter system, and is applied to an electric vehicle, for example.

Also in this case, with a low-cost configuration, increase in forward voltage due to turning on of the gate when the diode is in a conducting state can be prevented and breakdown due to type-3 short-circuit can be prevented, whereby the power conversion device 100C with low loss and high reliability is obtained.

The power converter 101 in the power conversion device 100C may be an inverter capable of multilevel voltage output. The power converter 102 in the power conversion device 100C is not limited to a boost converter, and may be a buck converter, or a buck-boost converter formed by combining a boost converter and a buck converter.

For the drive device 10X for the reverse conduction semiconductor switching elements, the drive device 10A for the reverse conduction semiconductor switching element according to embodiment 1 is used as an example. However, the drive devices 10B to 10D for the reverse conduction semiconductor switching element according to embodiments 2 to 4 may be used, whereby the same effects are obtained. Also in this case, the drive device 10X for the reverse conduction semiconductor switching elements is a set of the drive devices 10B to 10D for the reverse conduction semiconductor switching elements, which respectively drive the reverse conduction semiconductor switching elements 90.

In the above embodiments, all the reverse conduction semiconductor switching elements 90 have been described as reverse conduction IGBTs. However, a wide bandgap semiconductor material may be used for some of the reverse conduction semiconductor switching elements 90. In this case, switching operations of the reverse conduction semiconductor switching elements 90 can be made fast and the boost reactor 96 can be downsized. As the wide bandgap semiconductor material, silicon carbide SiC, gallium nitride, a gallium oxide-based material, or diamond may be used.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

10A to 10D, 10X drive device for reverse conduction semiconductor switching element
20 voltage reduction unit
30 first voltage determination unit
40 second voltage determination unit
50 short-circuit detection unit
60 ON-permission signal generation unit
70A, 70B gate drive unit
70C1, 70D1 first gate drive unit
70C2, 70D2 second gate drive unit
90 reverse conduction semiconductor switching element
91 leg circuit
92 AC motor
92A DC load
93, 95, 97 smoothing capacitor
94 DC power supply
96 boost reactor
100A to 100C power conversion device
101, 102 power converter
SIN ON/OFF command signal
SDE first voltage input signal
SCH first voltage determination signal
SGS ON permission start signal
SDD second voltage input signal
SGC second voltage determination signal
SGR ON permission stop signal
SSS short-circuit detection input signal
SSC short-circuit detection signal
SGD ON-permission signal
GDD buffer input signal

1.-15. (canceled)

16. A drive device for a reverse conduction semiconductor switching element in which a semiconductor switching element having a first main terminal, a second main terminal, and a gate terminal, and a rectification element connected in antiparallel to the semiconductor switching element, are integrated, the drive device comprising:
ON-permission signal generation circuitry which receives an ON/OFF command signal for turning on or off the reverse conduction semiconductor switching element and generates an ON-permission signal;
gate drive circuitry which receives the ON-permission signal and generates drive voltage to be applied to the gate terminal;
first voltage determination circuitry which includes a comparator for receiving inter-main terminal voltage between the first main terminal and the second main terminal, and performs comparison and determination between the inter-main terminal voltage and first reference voltage; and
second voltage determination circuitry which includes a comparator for receiving the inter-main terminal voltage, and performs comparison and determination between the inter-main terminal voltage and second reference voltage which is different from the first reference voltage, wherein
the ON-permission signal generation circuitry is configured to, on the basis of logical combination of a first voltage determination signal from the first voltage determination circuitry and the ON/OFF command signal, and logical combination of a second voltage determination signal from the second voltage determination circuitry and the ON/OFF command signal, if the inter-main terminal voltage in a period in which the reverse conduction semiconductor switching element is turned off is greater than the first reference voltage, set the ON-permission signal into an ON state, and if the inter-main terminal voltage in a period in which the reverse conduction semiconductor switching element is turned off is smaller than the second reference voltage, change the ON-permission signal into an OFF state.

17. The drive device for the reverse conduction semiconductor switching element according to claim 16, wherein
the ON-permission signal generation circuitry includes a state retention circuit, and
if the ON-permission signal is changed into an ON state, the ON-permission signal is retained in the ON state by the state retention circuit until the ON-permission signal is changed into an OFF state or the ON/OFF command signal indicates OFF, and if the ON-permission signal is changed into an OFF state, the ON-permission signal is retained in the OFF state by the state retention circuit until the ON-permission signal is changed into an ON state.

18. The drive device for the reverse conduction semiconductor switching element according to claim 16, wherein
the first reference voltage of the first voltage determination circuitry is greater than the second reference voltage.

19. The drive device for the reverse conduction semiconductor switching element according to claim 16, wherein
the second reference voltage of the second voltage determination circuitry is zero or a negative value.

20. The drive device for the reverse conduction semiconductor switching element according to claim 16, further comprising short-circuit detection circuitry which receives the ON-permission signal and the first voltage determination signal from the first voltage determination circuitry, and if the ON-permission signal is in an ON state and the inter-main terminal voltage is greater than the first reference voltage, determines a short-circuit state of the reverse conduction semiconductor switching element, and
the ON-permission signal generation circuitry receives a detection signal from the short-circuit detection circuitry, and if short-circuit of the reverse conduction semiconductor switching element is detected, the ON-permission signal generation circuitry changes the ON-permission signal into an OFF state.

21. The drive device for the reverse conduction semiconductor switching element according to claim 20, wherein
the short-circuit detection circuitry includes a state retention circuit which retains, for at least a predetermined period, a state in which short-circuit of the reverse conduction semiconductor switching element is detected.

22. The drive device for the reverse conduction semiconductor switching element according to claim 20, wherein
the gate drive circuitry generates the drive voltage to be applied to the gate terminal, through logical combination of the detection signal from the short-circuit detection circuitry and the ON-permission signal.

23. The drive device for the reverse conduction semiconductor switching element according to claim 16, wherein
voltage reduction circuitry is provided between the first and second voltage determination circuitry and the first main terminal, and reduces the inter-main terminal voltage to be applied to the first and second voltage determination circuitry.

24. The drive device for the reverse conduction semiconductor switching element according to claim 16, wherein
the reverse conduction semiconductor switching element is a multi-gate semiconductor switching element in which the gate terminal includes at least one first gate terminal and at least one second gate terminal which is different from the first gate terminal.

25. The drive device for the reverse conduction semiconductor switching element according to claim 24, wherein
the gate drive circuitry includes
first gate drive circuitry which receives the ON-permission signal or the ON/OFF command signal, and generates drive voltage to be applied to the first gate terminal, and
second gate drive circuitry which receives the ON-permission signal and generates drive voltage to be applied to the second gate terminal, and
the first and second gate drive circuitry is different in timings of the drive voltages to be applied to the first and second gate terminals, respectively.

26. The drive device for the reverse conduction semiconductor switching element according to claim 25, wherein
the first gate drive circuitry includes a delay circuit which delays an OFF timing of the ON-permission signal, and the second gate drive circuitry includes a delay circuit which delays an ON timing of the ON-permission signal.

27. A drive device for a reverse conduction semiconductor switching element in which a semiconductor switching element having a first main terminal, a second main terminal, and a gate terminal, and a rectification element connected in antiparallel to the semiconductor switching element, are integrated, the drive device comprising:
ON-permission signal generation circuitry which receives an ON/OFF command signal for turning on or off the reverse conduction semiconductor switching element and generates an ON-permission signal;
gate drive circuitry which receives the ON-permission signal and the ON/OFF command signal, and generates drive voltage to be applied to the gate terminal; and
voltage determination circuitry which receives inter-main terminal voltage between the first main terminal and the second main terminal, and performs comparison and determination between the inter-main terminal voltage and first reference voltage and second reference voltage which is different from the first reference voltage, respectively, wherein
the ON-permission signal generation circuitry is configured to, through logical combination of a determination signal from the voltage determination circuitry and the ON/OFF command signal, if the inter-main terminal voltage in a period in which the reverse conduction semiconductor switching element is turned off is greater than the first reference voltage, set the ON-permission signal into an ON state, and if the inter-main terminal voltage in a period in which the reverse conduction semiconductor switching element is turned off is smaller than the second reference voltage, change the ON-permission signal (SGD) into an OFF state, and
the gate drive circuitry is configured to, if the ON-permission signal is in an OFF state and the ON/OFF command signal has shifted from a state of indicating ON to a state of indicating OFF, set the ON-permission signal in an ON state for a first retention time.

28. The drive device for the reverse conduction semiconductor switching element according to claim 27, wherein
the reverse conduction semiconductor switching element is a multi-gate semiconductor switching element in which the gate terminal includes at least one first gate terminal and at least one second gate terminal which is different from the first gate terminal.

29. The drive device for the reverse conduction semiconductor switching element according to claim 28, wherein
the gate drive circuitry includes
first gate drive circuitry which receives the ON-permission signal or the ON/OFF command signal, and generates drive voltage to be applied to the first gate terminal, and
second gate drive circuitry which receives the ON-permission signal and generates drive voltage to be applied to the second gate terminal, and
the first and second gate drive circuitry is different in timings of the drive voltages to be applied to the first and second gate terminals, respectively.

30. The drive device for the reverse conduction semiconductor switching element according to claim 29, wherein
the first gate drive circuitry includes a delay circuit which delays an OFF timing of the ON-permission signal, and the second gate drive circuitry includes a delay circuit which delays an ON timing of the ON-permission signal.

31. A power conversion device comprising:
reverse conduction semiconductor switching elements in each of which a semiconductor switching element having a first main terminal, a second main terminal, and a gate terminal, and a rectification element connected in antiparallel to the semiconductor switching element, are integrated;
at least one leg circuit in which an upper arm and a lower arm each having the reverse conduction semiconductor switching element are connected in series; and
drive devices for reverse conduction semiconductor switching elements, respectively provided for the reverse conduction semiconductor switching elements of the upper arm and the lower arm, wherein
each of the drive devices for the reverse conduction semiconductor switching elements includes
ON-permission signal generation circuitry which receives an ON/OFF command signal for turning on or off the reverse conduction semiconductor switching element and generates an ON-permission signal, and
gate drive circuitry which receives the ON-permission signal and generates drive voltage to be applied to the gate terminal,
if inter-main terminal voltage between the first main terminal and the second main terminal in a period in which the reverse conduction semiconductor switching element is turned off is greater than first reference voltage, the ON-permission signal generation circuitry sets the ON-permission signal into an ON state, and if the inter-main terminal voltage is smaller than second reference voltage which is different from the first reference voltage, the ON-permission signal generation circuitry changes the ON-permission signal into an OFF state,
a dead time provided between the ON/OFF command signal for the upper arm and the ON/OFF command signal for the lower arm is set to be longer than a predetermined time, and
the time is a first retention time for retaining the ON-permission signal in an ON state if the ON-permission signal is in an OFF state and the ON/OFF command signal has shifted from a state of indicating ON to a state of indicating OFF.
